(19) United States
(12) Patent Application Publication
(10) Pub. No.: US 2026/0371581 A1
(43) Pub. Date: Nov. 19, 2026

(54) SEMICONDUCTOR DEVICE

(71) Applicant: SAMSUNG ELECTRONICS CO., LTD., Suwon-si (KR)

(72) Inventors: Kyunghwan KIM, Suwon-si (KR); Hyungeun CHOI, Suwon-si (KR); Keunnam KIM, Suwon-si (KR); Seokhan PARK, Suwon-si (KR); Seokho SHIN, Suwon-si (KR); Joongchan SHIN, Suwon-si (KR); Kiseok LEE, Suwon-si (KR); Sangho LEE, Suwon-si (KR); Moonyoung JEONG, Suwon-si (KR)

(73) Assignee: SAMSUNG ELECTRONICS CO., LTD., Suwon-si (KR)

(21) Appl. No.: 19/755,162

(22) Filed: Jul. 27, 2026

Related U.S. Application Data
(63) Continuation of application No. 18/518,293, filed on Nov. 22, 2023, now Pat. No. 12,740,055.

(30) Foreign Application Priority Data
Nov. 22, 2022 (KR) 10-2022-0157645

(51) Int. Cl. H10B 12/00

(52) U.S. Cl. CPC H10B 12/50; H10B 12/09; H10B 12/315

(57) ABSTRACT

A semiconductor device is provided. The semiconductor device includes: a lower structure including a bit line; a cell semiconductor body vertically overlapping the bit line, on the lower structure; a peripheral semiconductor body including a portion disposed on a same level as at least a portion of the cell semiconductor body, on the lower structure; and a peripheral gate on the peripheral semiconductor body, wherein the peripheral semiconductor body includes a lower region having a first width and an upper region having a second width, greater than the first width on the lower region.

### CROSS-REFERENCE TO RELATED APPLICATION(S)

This application is a Continuation of U.S. patent application Ser. No. 18/518,293, filed on Nov. 22, 2023, which claims priority under 35 U.S.C. § 119 to Korean Patent Application No. 10-10-2022-0157645, filed on Nov. 22, 2022, in the Korean Intellectual Property Office, the disclosure of which are incorporated herein by reference in their entireties herein.

### TECHNICAL FIELD

Example embodiments of the present disclosure relate to a semiconductor device and a method of manufacturing the same, and more particularly to a semiconductor device including a peripheral semiconductor body.

### DISCUSSION OF RELATED ART

Typically, semiconductor device performance may be improved by reducing a size of the elements of the semiconductor device. These elements may include components of transistors, for example. Reductions in the size of the elements may lead to higher element density, improved power efficiency, and lower manufacturing costs. As the size of the elements is reduced, it is becoming increasingly difficult to implement transistors having a desired level of performance, for example, due to challenges related to heat dissipation and design complexity.

### SUMMARY

Some embodiments of the present disclosure may provide a semiconductor device having an increased degree of integration and improved performance.

An example embodiment of the present disclosure may provide a method of forming a semiconductor device having an increased degree of integration and improved performance.

According to an example embodiment of the present disclosure, a semiconductor device is provided. The semiconductor device includes: a lower structure including a bit line; a cell semiconductor body vertically overlapping the bit line; a peripheral semiconductor body including a portion disposed on a same level as at least a portion of the cell semiconductor body, on the lower structure; and a peripheral gate on the peripheral semiconductor body, wherein the peripheral semiconductor body includes a lower region having a first width and an upper region having a second width, greater than the first width on the lower region.

According to an example embodiment of the present disclosure, a semiconductor device is provided. The semiconductor device includes: a lower structure; a vertical channel transistor disposed on the lower structure; a peripheral semiconductor body disposed on the lower structure; a peripheral device isolation region disposed on a side surface of the peripheral semiconductor body, on the lower structure; a peripheral gate on an upper surface of the peripheral semiconductor body; and peripheral source/drain regions in the peripheral semiconductor body on both sides of the peripheral gate, wherein the vertical channel transistor includes: a lower cell source/drain region disposed in a lower region of a cell semiconductor body; an upper cell source/drain region disposed in an upper region of the cell semiconductor body; a cell channel region disposed in the cell semiconductor body between the lower cell source/drain region and the upper cell source/drain region; a cell gate electrode facing a first side surface of the cell channel region; and a cell gate dielectric layer between the first side surface of the cell channel region and the cell gate electrode, wherein the lower structure includes a lower insulating layer and a bit line electrically connected to the lower cell source/drain region, wherein the peripheral device isolation region includes a gap-fill insulating layer and a buffer liner between a side surface of the peripheral semiconductor body and a side surface of the gap-fill insulating layer, wherein a lower surface of the gap-fill insulating layer and a lower end portion of the buffer liner are in contact with the lower insulating layer of the lower structure.

According to an example embodiment of the present disclosure, a semiconductor device is provided. The semiconductor device includes: a lower structure; a plurality of vertical channel transistors disposed on the lower structure; a peripheral semiconductor body disposed on the lower structure, at least a portion of the peripheral semiconductor body having a negative slope; and a peripheral device isolation region on the side surface of the peripheral semiconductor body, on the lower structure, wherein each of the vertical channel transistors includes: a lower cell source/drain region disposed in a lower region of a cell semiconductor body; an upper cell source/drain region disposed in an upper region of the cell semiconductor body; a cell channel region disposed in the cell semiconductor body between the lower cell source/drain region and the upper cell source/drain region; a cell gate electrode facing a first side surface of the cell channel region; and a cell gate dielectric layer between the first side surface of the cell channel region and the cell gate electrode, wherein the lower structure includes: a plurality of bit lines electrically connected to the lower cell source/drain regions of the plurality of vertical channel transistors; and a shield structure including a line portion disposed between the bit lines, wherein the peripheral device isolation region includes: a gap-fill insulating layer; and an insulating liner between a side surface of the peripheral semiconductor body and a side surface of the gap-fill insulating layer, wherein an upper end portion of the peripheral semiconductor body is disposed at a first height level, a lower end portion of the peripheral semiconductor body is disposed at a second height level, an upper end portion of the insulating liner is disposed at a third height level, and a lower end portion of the insulating liner is disposed at a fourth height level, wherein a first difference between the first height level and the third height level is different from a second difference between the second height level and the fourth height level.

### BRIEF DESCRIPTION OF THE DRAWINGS

The above and other aspects, features, and advantages of the present disclosure will be more clearly understood from the following detailed description, taken in combination with the accompanying drawings, in which:

FIG. 1, FIG. 2A, FIG. 2B, and FIG. 2C are diagrams illustrating a semiconductor device according to an example embodiment of the present disclosure;

FIG. 3A is a cross-sectional view illustrating a modified example of a semiconductor device according to an example embodiment of the present disclosure;

FIG. 3B is a cross-sectional view illustrating a modified example of a semiconductor device according to an example embodiment of the present disclosure;

FIG. 3C is a cross-sectional view illustrating a modified example of a semiconductor device according to an example embodiment of the present disclosure;

FIG. 4 is a process flow diagram illustrating example embodiments of a method of forming a semiconductor device according to an example embodiment of the present disclosure; and

FIG. 5, FIG. 6A, FIG. 6B, FIG. 6C, FIG. 7, FIG. 8, FIG. 9, FIG. 10, FIG. 11A, FIG. 11B, FIG. 11C, FIG. 12A, FIG. 12B, FIG. 12C, FIG. 13A, FIG. 13B, FIG. 13C, FIG. 14A, FIG. 14B, and FIG. 14C are cross-sectional views illustrating example embodiments of a method of forming a semiconductor device according to an example embodiment of the present disclosure.

### DETAILED DESCRIPTION

Hereinafter, embodiments of the present disclosure will be described as follows with reference to the accompanying drawings. Hereinafter, terms such as “upper,” “middle,” and “lower” may be replaced with other terms such as “first,” “second,” and “third” and used to describe elements of the disclosure. Terms such as “first,” “first lower,” “first intermediate,” “first upper,” “second,” “second lower,” “second intermediate,” “second upper,” “third,” “third lower,” “third intermediate,” and “third upper” may be used to describe various elements, but the elements are not limited by the above terms. For example, a “first component” may be referred to as a “second component.” Likewise, the “second lower component” may be referred to as a “first component” and the “second upper component” may be referred to as a “first component.”

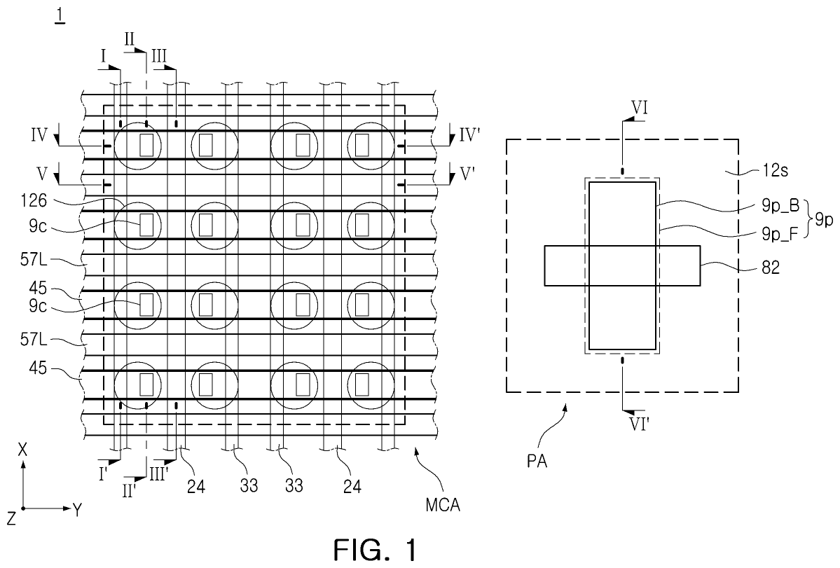

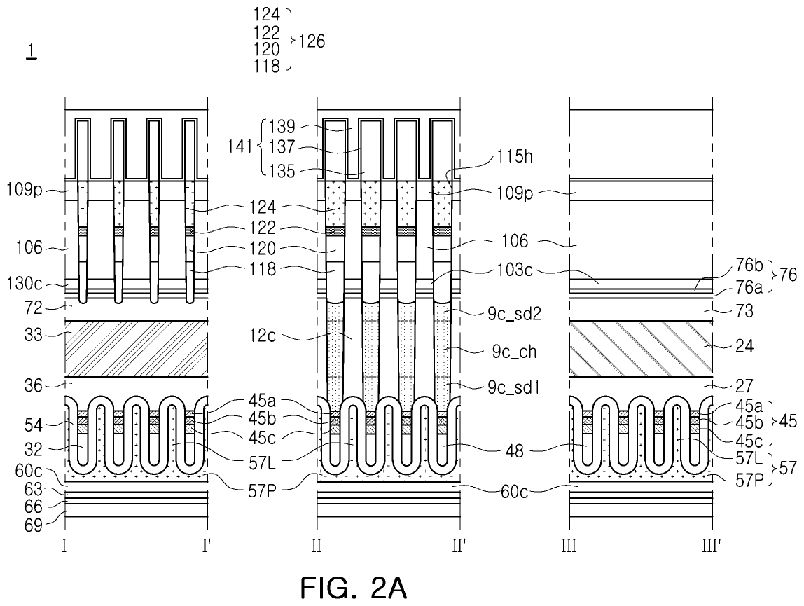

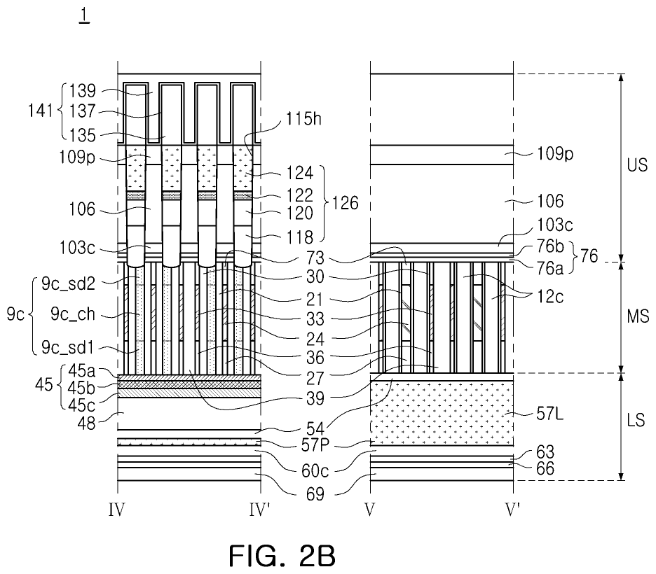

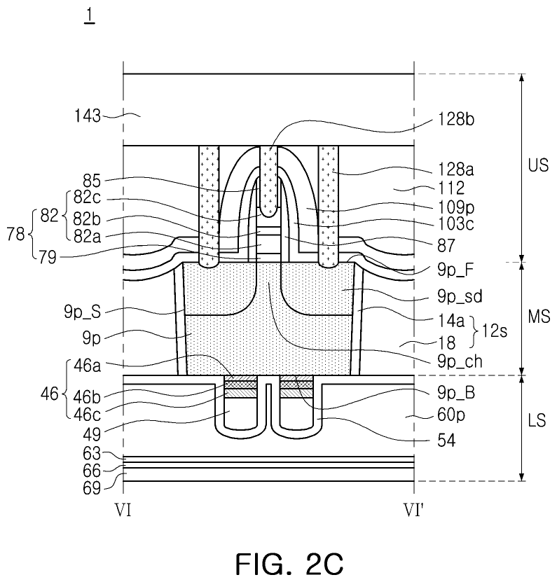

Referring to FIG. 1, FIG. 2A, FIG. 2B, and FIG. 2C, a semiconductor device according to an example embodiment of the present disclosure will be described. FIG. 1 is a top view conceptually illustrating a semiconductor device according to an example embodiment of the present disclosure. FIG. 2A is a cross-sectional view illustrating a region taken along lines I-I′, II-II′, and III-III′ of FIG. 1. FIG. 2B is a cross-sectional view illustrating a region taken along lines IV-IV′ and V-V′ of FIG. 1. FIG. 2C is a cross-sectional view illustrating a region taken along line VI-VI′ of FIG. 1.

Referring to FIG. 1, FIG. 2A, FIG. 2B, and FIG. 2C, a semiconductor device 1 according to an example embodiment may include a cell array region MCA and a peripheral circuit region PA. The semiconductor device 1 may include a lower structure LS, an intermediate structure MS on the lower structure LS, and an upper structure US on the intermediate structure MS.

The lower structure LS may include bit lines 45 disposed in the cell array region MCA.

Each of the bit lines 45 may include at least one conductive material layer. For example, each of the bit lines 45 may include a first conductive layer 45a, a second conductive layer 45b below the first conductive layer 45a, and a third conductive layer 45c below the second conductive layer 45b.

The first conductive layer 45a may include doped polysilicon, for example, polysilicon having N-type conductivity. The second conductive layer 45b may include at least one of a metal-semiconductor compound layer or a conductive barrier layer. For example, the metal-semiconductor compound layer may include at least one of a tungsten silicide (Wsi), titanium silicide (TiSi), tantalum silicide (TaSi), nickel silicide (NiSi), or cobalt silicide (CoSi), and the conductive barrier layer may include at least one of titanium nitride (TiN), tantalum nitride (TaN), tungsten nitride (WN), titanium silicide nitride (TiSiN), tantalum silicide nitride (TaSiN), or ruthenium titanium nitride (RuTiN). The third conductive layer 45c may include a metal material such as W.

Within the cell array region MCA, the lower structure LS may further include a shield structure 57 including line portions 57L disposed between bit lines 45 (see FIG. 2A). The shield structure 57 may be formed of a conductive material. For example, the shield structure 57 may include doped polysilicon, metal, conductive metal nitride, metal-semiconductor compound, conductive metal oxide, graphene, carbon nanotube, or combinations thereof. The shield structure 57 may also be referred to as a bit line shield structure.

The shield structure 57 may further include a plate portion 57P extending from the line portions 57L disposed between the bit lines 45 and disposed below the bit lines 45 (see FIG. 2A and FIG. 2B).

The shield structure 57 may serve to screen capacitive coupling between the bit lines 45, adjacent to each other. For example, the shield structure 57 may minimize a resistive-capacitive (RC) delay in the bit lines 45, by reducing or blocking parasitic capacitance between the bit lines 45, adjacent to each other.

The lower structure LS may further include bit line capping layers 48 disposed below the bit lines 45 (see FIG. 2A and FIG. 2B). The bit line capping layers 48 may include an insulating material such as silicon nitride, or the like.

The lower structure LS may further include a peripheral conductive pattern 46 disposed within the peripheral circuit region PA and a peripheral capping pattern 49 below the peripheral conductive pattern 46 (see FIG. 2C). The peripheral conductive pattern 46 may be referred to as a body control conductive pattern.

At least a portion of the peripheral conductive pattern 46 may be disposed at a same level as the bit lines 45. The peripheral capping pattern 49 may be formed of the same material as the bit line capping layers 48. At least a portion of the peripheral conductive pattern 46 may include the same material as the bit lines 45. For example, like the bit lines 45, the peripheral conductive pattern 46 may include a first conductive layer 46a, a second conductive layer 46b below the first conductive layer 46a, and a third conductive layer 46c below the second conductive layer 46b.

The lower structure LS may further include a lower insulating layer 54. Within the cell array region MCA, the lower insulating layer 54 may be disposed between the bit lines 45 and the shield structure 57, and between the bit line capping layers 48 and the shield structure 57. Within the cell array region MCA, the lower insulating layer 54 may cover upper portions of the line portions 57L of the shield structure 57. Within the peripheral circuit region PA, the lower insulating layer 54 may cover a side surface of the peripheral conductive pattern 46, and a side surface and a lower surface of the peripheral capping pattern 49, and be in contact with the intermediate structure MS. The lower insulating layer 54 may include an insulating material such as silicon oxide or silicon nitride. The lower insulating layer 54 may also be referred to as a lower insulating liner, or a lower insulating liner layer.

Within the cell array region MCA, the lower structure LS may further include a shield capping insulating layer 60c below the shield structure 57 (see FIG. 2A and FIG. 2B).

Within the peripheral circuit region PA, the lower structure LS may further include a peripheral lower insulating layer 60p disposed below the lower insulating layer 54 (see FIG. 2C).

The lower structure LS may further include at least one lower protective layer disposed below the shield structure 57 and the peripheral lower insulating layer 60p. The lower protective layers may include a first lower protective layer, a second lower protective layer below the first lower protective layer, and a third lower protective layer, below the second lower protective layer. The lower protective layers may include an insulating material. That is, the first lower protective layer may be insulating layer 63, the second lower protective layer may be insulating layer 66, and the third lower protective layer may be support layer 69.

The intermediate structure MS may include cell semiconductor bodies 9c, a peripheral semiconductor body 9p, and a peripheral device isolation region 12s.

The cell semiconductor bodies 9c may be disposed within the cell array region MCA. The cell semiconductor bodies 9c may be disposed on the lower structure LS. The cell semiconductor bodies 9c on the lower structure LS may vertically overlap the bit lines 45. The cell semiconductor bodies 9c may be arranged in a first horizontal direction X and a second horizontal direction Y, wherein the second horizontal direction Y may be perpendicular to the first horizontal direction X.

Hereinafter, one cell semiconductor body among the cell semiconductor bodies 9c will be described as an example.

The cell semiconductor body 9c may be formed of a semiconductor material. For example, the cell semiconductor body 9c may be formed of a single crystal semiconductor material. The cell semiconductor body 9c may include a group IV semiconductor, a group III-V compound semiconductor, or a group II-VI compound semiconductor. The cell semiconductor body 9c may be a single crystal semiconductor including at least one of silicon, silicon carbide, germanium, or silicon-germanium. For example, the cell semiconductor body 9c may include single crystal silicon patterns or single crystal silicon carbide patterns. The cell semiconductor body 9c may also be referred to as a semiconductor pattern or a silicon pattern.

The peripheral semiconductor body 9p may be disposed within the peripheral circuit region PA and may be disposed on the lower structure LS. The peripheral semiconductor body 9p may be formed of the same material as the cell semiconductor body 9c. At least a portion of the peripheral semiconductor body 9p may be disposed at a same level as the cell semiconductor body 9c.

At least a portion of a side surface 9p_S of the peripheral semiconductor body 9p may have a negative slope. The peripheral semiconductor body 9p may include a lower region having a first width and an upper region having a second width, greater than the first width on the lower region, to have the side surface 9p_S having a negative slope. The peripheral semiconductor body 9p may include a lower surface 9p_B and an upper surface 9p_F having a greater width than the lower surface 9p_B. In the peripheral semiconductor body 9p, the lower surface 9p_B may be referred to as a first surface, and the upper surface 9p_F may be referred to as a second surface.

The peripheral semiconductor body 9p may include peripheral source/drain regions 9p_sd, spaced apart from each other and a peripheral channel region 9p_ch between the peripheral source/drain regions 9p_sd. The peripheral source/drain regions 9p_sd may be disposed within an upper region of the peripheral semiconductor body 9p.

The peripheral device isolation region 12c may contact the side surface 9p_S of the peripheral semiconductor body 9p.

The peripheral device isolation region 12c may include a buffer liner 14a and a gap-fill insulating layer 18. The buffer liner 14a may be disposed between the gap-fill insulating layer 18 and the peripheral semiconductor body 9p. The buffer liner 14a may include at least one insulating material. For example, the buffer liner 14a may include at least one of silicon oxide or silicon nitride. For example, the buffer liner 14a may be formed of a silicon oxide layer. The gap-fill insulating layer 18 may include at least one of silicon oxide or a low-κ dielectric. The low-κdielectric may be an insulating material having a dielectric constant greater than that of silicon oxide.

The cell semiconductor body 9c may include a first source/drain region 9c_sd1, a second source/drain region 9c_sd2 on the first source/drain region 9c_sd1, and a channel region 9c_ch between the first and second source/drain regions 9c_sd1 and 9c_sd2. The channel region 9c_ch may be a vertical channel region.

The first source/drain region 9c_sd1 may be referred to as a lower cell source/drain region, and the second source/drain region 9c_sd2 may be referred to as an upper cell source/drain region.

The first source/drain region 9c_sd1 may be electrically connected to the bit line 45.

The intermediate structure MS may further include cell gate electrodes 33, parallel to each other and back gate electrodes 24, parallel to each other. The pair of cell gate electrodes 33, adjacent to each other may be disposed between the pair of back gate electrodes 24. The cell gate electrodes 33 may be word lines.

Each of the cell gate electrodes 33 and the back gate electrodes 24 may have a linear shape extending in a first horizontal direction X.

In the top view of FIG. 1, the cell gate electrodes 33 and the back gate electrodes 24 illustrated in a linear shape are conceptually represented, and a width of the cell gate electrodes 33 and the back gate electrodes 24 may be changed depending on a position thereof.

A width of each of the cell gate electrodes 33 may be different from that of each of the back gate electrodes 24. For example, the width of each of the cell gate electrodes 33 may be narrower than that of each of the back gate electrodes 24.

Among the cell semiconductor bodies 9c, the channel region 9c_ch of a cell semiconductor body 9c may be disposed between a back gate electrode 24 and a cell gate electrode 33, adjacent to each other, among the back gate electrodes 24 and the cell gate electrodes 33. Accordingly, the cell gate electrode 33, which may be a word line, may be disposed on a first side surface of the cell semiconductor body 9c, and the back gate electrode 24 may be disposed on a second side surface of the cell semiconductor body 9c. This, the cell gate electrode 33 may face the first side surface of the cell semiconductor body 9c, and the back gate electrode 24 may face the second side surface of the cell semiconductor body 9c.

The intermediate structure MS may further include an insulating layer 36 below the cell gate electrode 33 and an insulating layer 72 on the cell gate electrode 33. The insulating layer 36 below the cell gate electrode 33 may be referred to as a cell gate lower capping layer, and the insulating layer 72 on the cell gate electrode 33 may be referred to as a cell gate upper capping layer.

The intermediate structure MS may further include an insulating layer 27 below the back gate electrode 24 and an insulating layer 73 on the back gate electrode 24. The insulating layer 27 below the back gate electrode 24 may be referred to as a back gate lower capping layer, and the insulating layer 73 on the back gate electrode 24 may be referred to as a back gate upper capping layer.

The intermediate structure MS may further include a back gate dielectric layer 21 between the cell semiconductor body 9c and the back gate electrode 24, and a cell gate dielectric layer 30 between the cell semiconductor body 9c and the cell gate electrode 33.

The cell gate dielectric layer 30, the cell gate electrode 33, the first source/drain region 9c_sd1, the second source/drain region 9c_sd2, and the channel region 9c_ch may form a cell transistor. The cell transistor may be referred to as a cell vertical transistor, a vertical transistor, or a vertical channel transistor. Accordingly, the intermediate structure MS may include the cell transistor.

The back gate electrode 24 may suppress or prevent a floating body effect occurring in the channel region 9c_ch of the cell transistor, and prevent a threshold voltage of the cell transistor from being varied. Thus, the back gate electrode 24 can stably operate the cell transistor.

The intermediate structure MS may further include an insulating layer 39 between the pair of cell gate electrodes 33, adjacent to each other.

A cell device isolation region 12c extending in the first horizontal direction X may be further included. The cell device isolation region 12c may include an insulating material such as silicon oxide, or the like. The cell semiconductor body 9c may have a first side surface, in contact with the cell gate dielectric layer 30, a second side surface, in contact with the back gate dielectric layer 21, and a third side surface, in contact with the cell device isolation region 12c.

Within the cell array region MCA, the upper structure US may include a buffer insulating layer 76, a lower insulating liner layer 103c, a cell interlayer insulating layer 106, and an upper insulating liner layer 109p, sequentially stacked. The buffer insulating layer 76 may include at least one layer, for example, a first buffer insulating layer 76a and a second buffer insulating layer 76b, sequentially stacked.

Within the cell array region MCA, the upper structure US may further include cell contact structures 126 in holes 115h. The holes 115h may penetrate through the buffer insulating layer 76, the lower insulating liner layer 103c, the cell interlayer insulating layer 106, and the upper insulating liner layer 109p. The cell contact structures 126 in holes 115h may be electrically connected to the second source/drain regions 9c_sd2.

Each of the cell contact structures 126 may include a first layer 118, a second layer 120, a third layer 122, and a fourth layer 124, which may be sequentially stacked.

In an example, the first layer 118 may include epitaxial silicon, e.g., epitaxial silicon having N-type conductivity. When the first layer 118 is formed of epitaxial silicon, the second layer 120 may include polysilicon, for example, polysilicon having N-type conductivity.

In another example, the first layer 118 may include polysilicon, for example, polysilicon having N-type conductivity. When the first layer 118 is formed of polysilicon, the first layer 118 and the second layer 120 may be formed as a single layer.

The third layer 122 may include at least one of a metal-semiconductor compound layer or a conductive barrier layer. For example, the metal-semiconductor compound layer may include at least one of WSi, TiSi, TaSi, NiSi, or CoSi, and the conductive barrier layer may include at least one of TiN, TaN, WN, TiSiN, TaSiN, or RuTiN. The fourth layer 124 may include a conductive material such as W.

Within the cell array region MCA, the upper structure US may further include a data storage structure 141. The data storage structure 141 may include first electrodes 135 electrically connected to the cell contact structures 126, a dielectric layer 137 on the first electrodes 135, and a second electrode 139 on the dielectric layer 137.

In one example, the data storage structure 141 may be a capacitor storing information in a Dynamic Random-Access Memory (DRAM). For example, the dielectric layer 137 of the data storage structure 141 may be a capacitor dielectric layer of a DRAM, and the dielectric layer 137 may include a high-k dielectric layer, silicon oxide, silicon nitride, silicon oxynitride, or a combination thereof.

In another example, the data storage structure 141 may be a structure for storing data and other memory information. For example, the data storage structure 141 may be disposed between the first electrodes 135 and the second electrodes 139, and may be a capacitor of a ferroelectric memory (FeRAM) including a dielectric layer including a ferroelectric layer. For example, the dielectric layer 137 may be a ferroelectric layer capable of recording data using a polarization state. When the data storage structure 141 is a capacitor for storing information of an FeRAM, the ferroelectric layer of the dielectric layer 137 may include an Hf-based compound, a Zirconium (Zr) based compound, and/or a Hafnium-Zirconium (Hf—Zr) based compound.

Within the peripheral circuit region PA, the upper structure US may include a peripheral gate 78. The peripheral gate 78 may include a peripheral gate dielectric layer 79, in contact with an upper surface 9p_F of the peripheral semiconductor body 9p, and a peripheral gate electrode 82 on the peripheral gate dielectric layer 79. The peripheral gate 78 may be disposed on the channel region 9p_ch of the peripheral semiconductor body 9p.

The peripheral gate electrode 82 may include a plurality of conductive layers. For example, the conductive layers of the peripheral gate electrode 82 may include a first conductive layer 82a, a second conductive layer 82b, and a third conductive layer 82c, sequentially stacked.

Within the peripheral circuit region PA, the upper structure US may further include a peripheral gate capping pattern 85 on the peripheral gate electrode 82 and a peripheral gate spacer 87 on side surfaces of the peripheral gate electrode 82 and the peripheral gate capping pattern 85.

Within the peripheral circuit region PA, the upper structure US may further include a lower insulating liner layer 103c covering the peripheral device isolation region 12s, the peripheral semiconductor body 9p, the peripheral gate electrode 82, the peripheral gate capping pattern 85, and the peripheral gate spacer 87, an upper insulating liner layer 109p on the lower insulating liner layer 103c, a peripheral interlayer insulating layer 112 on the upper insulating liner layer 109p, and an upper insulating layer 143 on the peripheral interlayer insulating layer 112.

Within the peripheral circuit region PA, the upper structure US may further include a peripheral source/drain contact plug 128a and a peripheral gate contact plug 128b.

The peripheral source/drain contact plug 128a may penetrate through the lower insulating liner layer 103c, the upper insulating liner layer 109p, and the peripheral interlayer insulating layer 112 within the peripheral circuit region PA, and be electrically connected to the peripheral source/drain region 9p_sd. The peripheral gate contact plug 128b may penetrate through the lower insulating liner layer 103c, the upper insulating liner layer 109p, and the peripheral gate capping pattern 85 within the peripheral circuit region PA, and be electrically connected to the peripheral gate electrode 82.

Within the peripheral circuit region PA, the lower insulating liner layer 103c, the upper insulating liner layer 109p, and the peripheral interlayer insulating layer 112 may form a peripheral insulating structure.

A lower end of the buffer liner 14a and a lower surface of the gap-fill insulating layer 18 may contact the lower insulating layer 54 of the lower structure LS.

An upper end of the buffer liner 14a and an upper surface of the gap-fill insulating layer 18 may contact the peripheral insulating structure, for example, the lower insulating liner layer 103c.

An upper surface of the gap-fill insulating layer 18 may be disposed at a level lower than that of an upper surface 9p_F of the peripheral semiconductor body 9p. A lower surface of the gap-fill insulating layer 18 may be disposed on substantially the same level as a lower surface 9p_B of the peripheral semiconductor body 9p.

A difference in heights between a level of the upper surface of the gap-fill insulating layer 18 and the level of the upper surface 9p_F of the peripheral semiconductor body 9p may be different from a difference in heights between the lower surface of the gap-fill insulating layer 18 and the lower surface 9p_B of the peripheral semiconductor body 9p.

The difference in heights between the level of the upper surface of the gap-fill insulating layer 18 and the level of the upper surface 9p_F of the peripheral semiconductor body 9p may be greater than the difference in heights between the lower surface of the gap-fill insulating layer 18 and the lower surface 9p_B of the peripheral semiconductor body 9p.

Within the peripheral circuit region PA, since a width of an upper region of the peripheral semiconductor body 9p may be greater than a width of a lower region thereof, and the peripheral source/drain regions 9p_sd may be disposed in the upper region of the peripheral semiconductor body 9p, volumes of the peripheral source/drain regions 9p_sd may be further increased. Accordingly, performance of a peripheral transistor including the peripheral source/drain regions 9p_sd, the peripheral channel region 9p_ch, and the peripheral gate 78, including the peripheral gate dielectric layer 79 and the peripheral gate electrode 82, may be improved.

Hereinafter, modified examples will be described. Modified examples may be described with a focus on modified or replaced elements. In addition, elements that can be modified or replaced may be described with reference to certain drawings, but the elements may be combined with each other or with other elements described herein to form a semiconductor device according to example embodiments of the present disclosure.

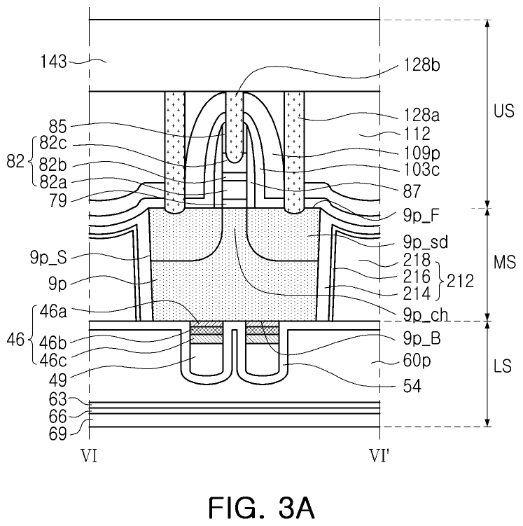

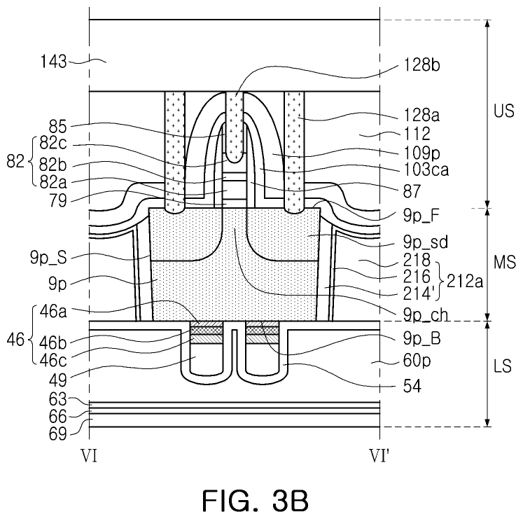

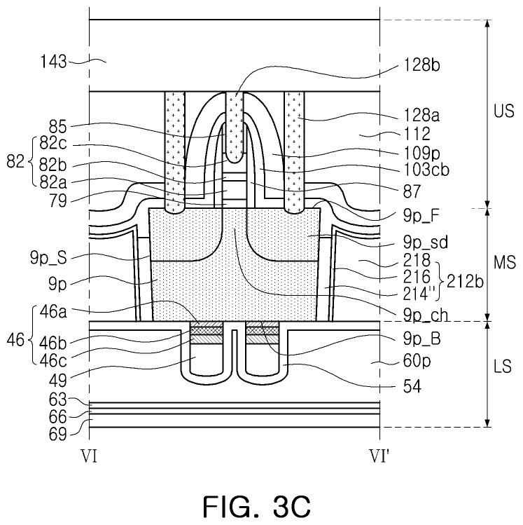

FIG. 3A, FIG. 3B, and FIG. 3C are cross-sectional views illustrating various modified examples of a semiconductor device according to an example embodiment of the present disclosure. In the cross-sectional structure of FIG. 2C illustrating a region taken along the line VI-VI′ of FIG. 1, various modified examples of the peripheral device isolation region (12s in FIG. 2C) may be illustrated.

In a modified example, referring to FIG. 3A, the peripheral device isolation region (12s of FIG. 2C) in FIG. 2C may be modified to be a peripheral device isolation region 212 as in FIG. 3A.

The peripheral device isolation region 212 may include a buffer liner 214, a second insulating liner 216, and a gap-fill insulating layer 218.

The buffer liner 214 may be disposed between a side surface of the gap-fill insulating layer 218 and a side surface 9p_S of the peripheral semiconductor body 9p. The buffer liner 214 may contact the side surface 9p_S of the peripheral semiconductor body 9p. The buffer liner 214 may further include a portion extending between an upper surface of the gap-fill insulating layer 218 and the peripheral insulating structure. The peripheral insulating structure may include the lower insulating liner layer 103c, the upper insulating liner layer 109p, and the peripheral interlayer insulating layer 112. Thus, the buffer liner 214 may cover a side surface and upper surface of the gap-fill insulating layer 218.

The second insulating liner 216 may be disposed between the buffer liner 214 and the gap-fill insulating layer 218. The second insulating liner 216 may contact a side surface and upper surface of the gap-fill insulating layer 218.

A lower end portion of the buffer liner 214, a lower end portion of the second insulating liner 216, and a lower surface of the gap-fill insulating layer 218 may contact the lower insulating layer 54 of the lower structure LS.

An upper end portion of the peripheral semiconductor body 9p may be disposed at a first height level, a lower end portion of the peripheral semiconductor body 9p may be disposed at a second height level, an upper end portion of the second insulating liner 216 may be disposed at a third height level, and a lower end portion of the second insulating liner 216 may be disposed at a fourth height level. Here, a first difference between the first height level and the third height level may be different from a second difference between the second height level and the fourth height level. The first difference between the first height level and the third height level may be greater than the second difference between the second height level and the fourth height level. The second difference between the second height level and the fourth height level may be greater than or equal to 0.

The buffer liner 214 may cover an upper surface of the second insulating liner 216 and isolate the second insulating liner 216 from the peripheral insulating structure including the lower insulating liner layer 103c, the upper insulating liner layer 109p, and the peripheral interlayer insulating layer 112.

In a modified example, referring to FIG. 3B, the peripheral device isolation region (212 of FIG. 3A) in FIG. 3A may be replaced with a peripheral device isolation region 212a including a first modified buffer liner 214′. For example, the first modified buffer liner 214′ may be disposed between a side surface of the gap-fill insulating layer 218 and a side surface 9p_S of the peripheral semiconductor body 9p, and may not cover an upper surface of the second insulating liner 216 on an upper surface of the gap-fill insulating layer 218. Accordingly, an upper end portion of the first modified buffer liner 214′ and an upper surface of the second insulating liner 216 may contact the peripheral insulating structure including the lower insulating liner layer 103c, the upper insulating liner layer 109p, and the peripheral interlayer insulating layer 112.

An upper end portion of the first modified buffer liner 214′ may be disposed at a higher level than that of an upper end portion of the second insulating liner 216, and may be disposed at a lower level than that of an upper surface of the peripheral semiconductor body 9p.

The lower insulating liner layer (103c in FIG. 3A) of the peripheral insulating structure described above may be modified to be a modified lower insulating liner layer 103ca covering a portion of side surfaces of the upper region of the peripheral semiconductor body 9p. In a modified example, referring to FIG. 3C, the peripheral device isolation region 212a in FIG. 3B may be replaced with a peripheral device isolation region 212b including a second modified buffer liner 214″. For example, the second modified buffer liner 214″ may be disposed between a side surface of the gap-fill insulating layer 218 and a side surface 9p_S of the peripheral semiconductor body 9p, and have an upper end portion located at a level lower than that of the second insulating liner 216.

The modified lower insulating liner layer (103ca in FIG. 3B) of the peripheral insulating structure described above may cover a portion of side surfaces of the upper region of the peripheral semiconductor body 9p, and may be modified to be a modified lower insulating liner layer 103cb extending between the peripheral semiconductor body 9p and the second insulating liner 216.

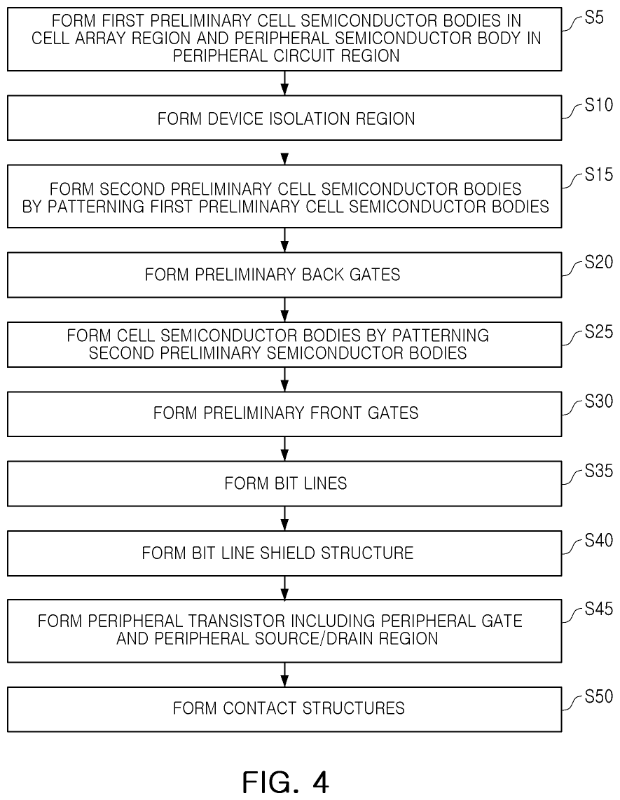

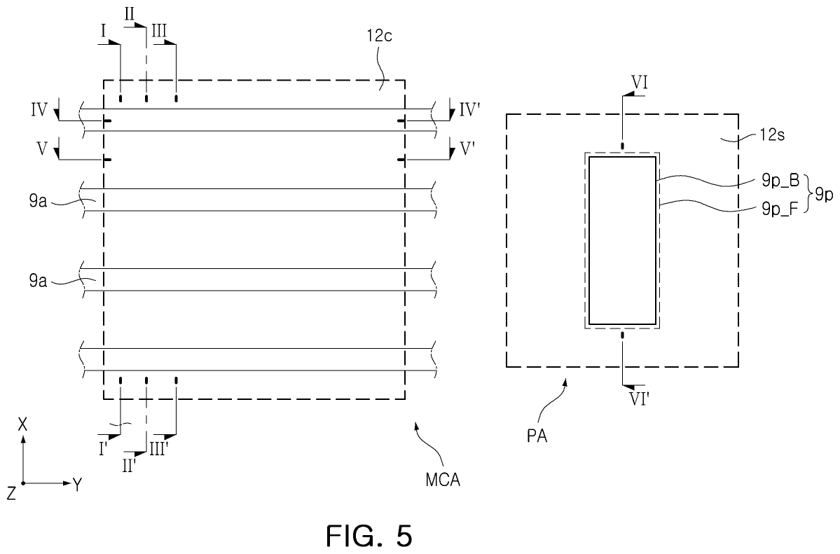

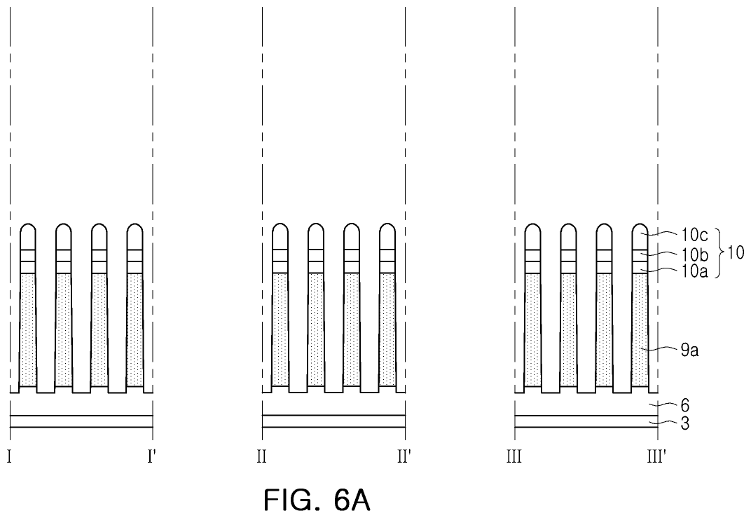

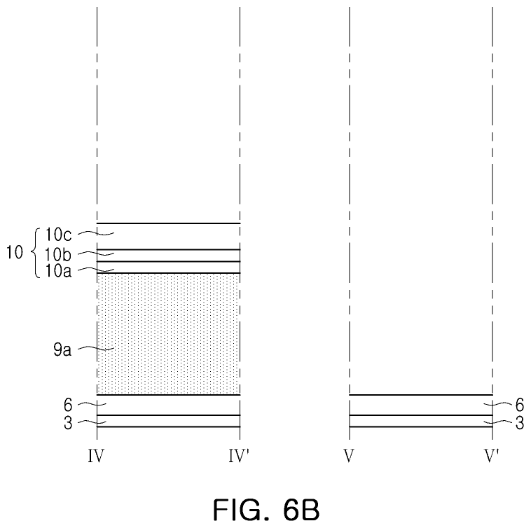

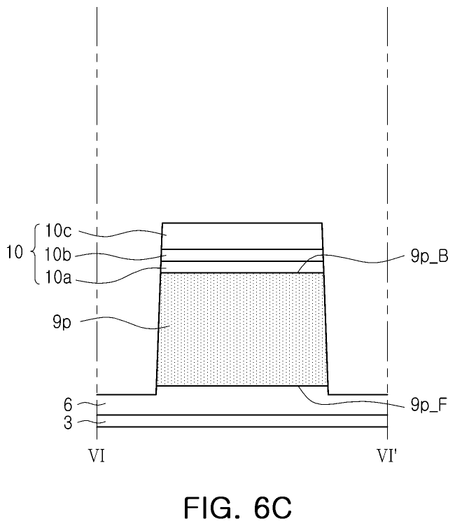

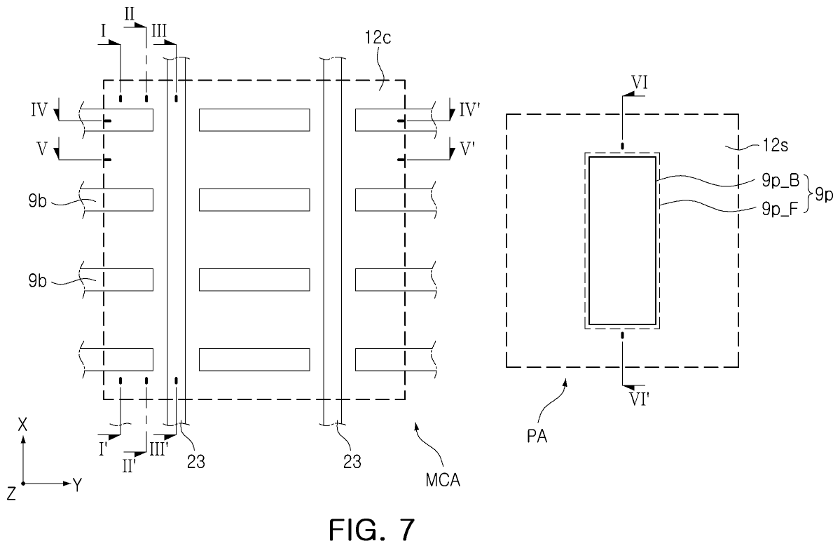

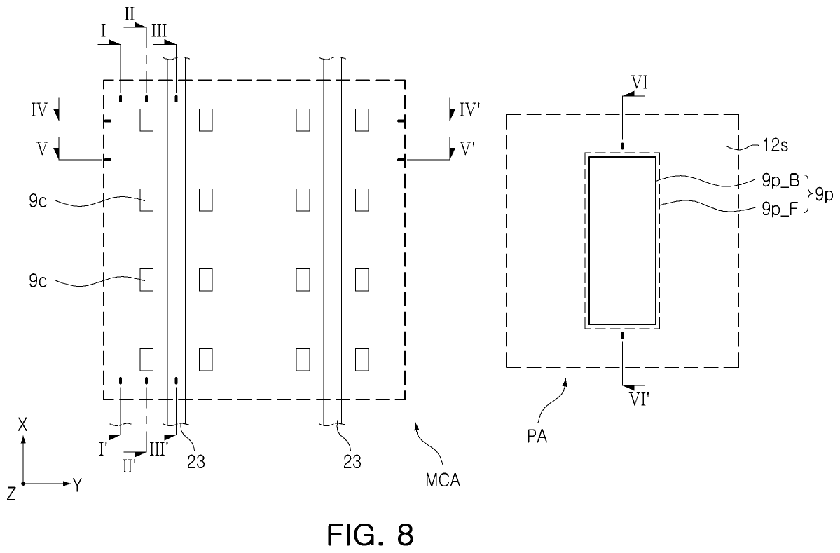

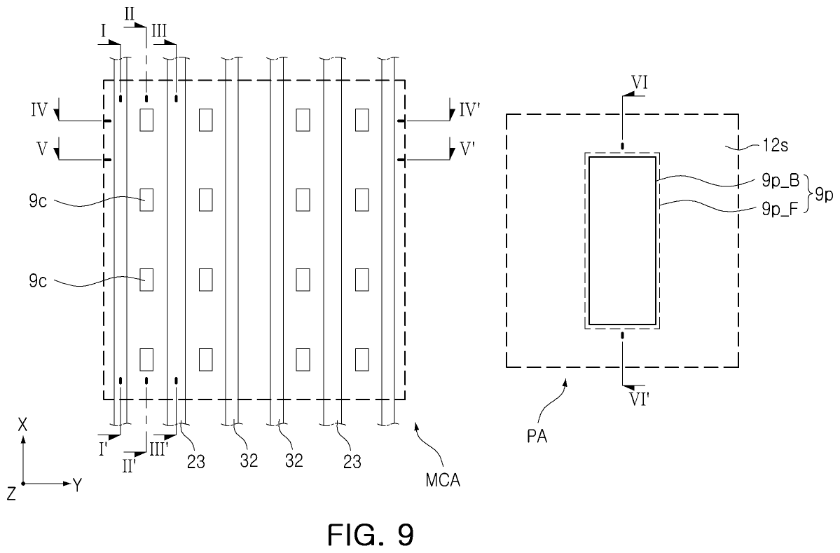

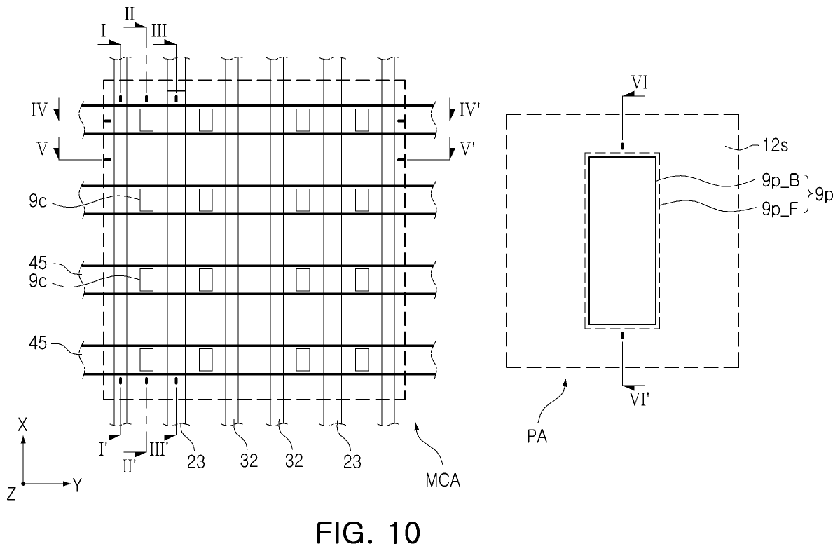

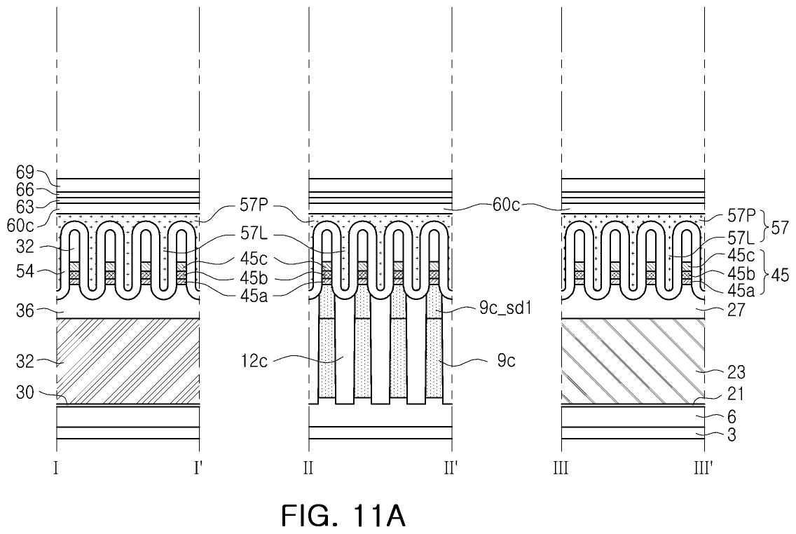

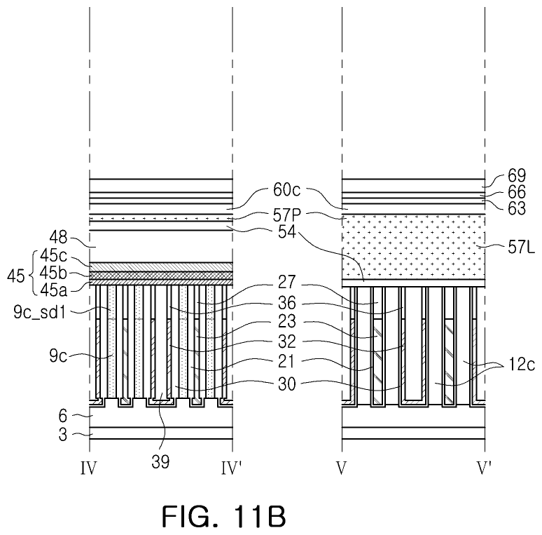

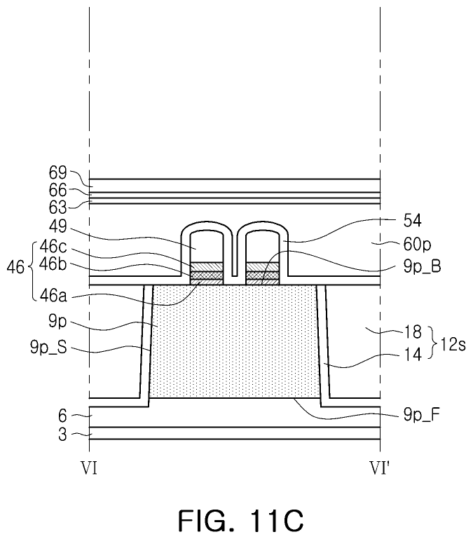

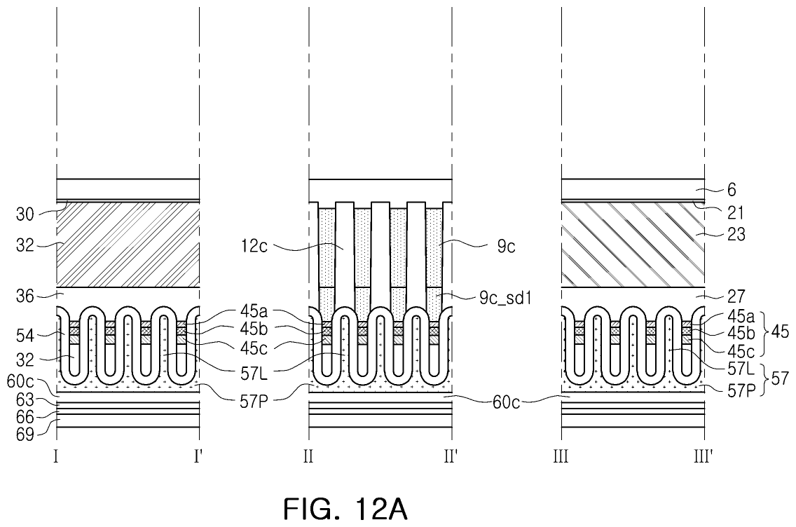

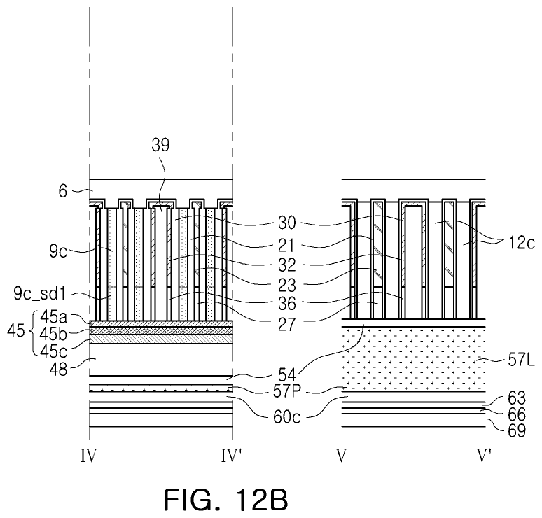

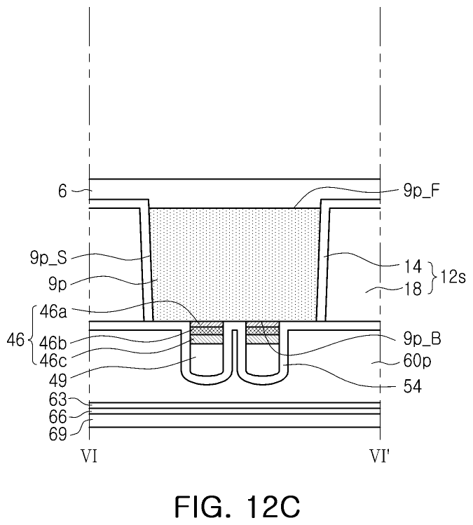

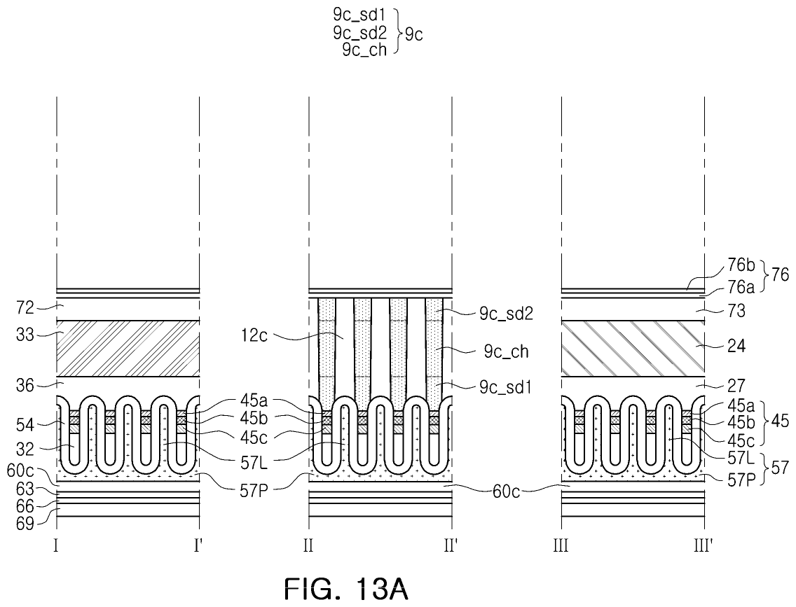

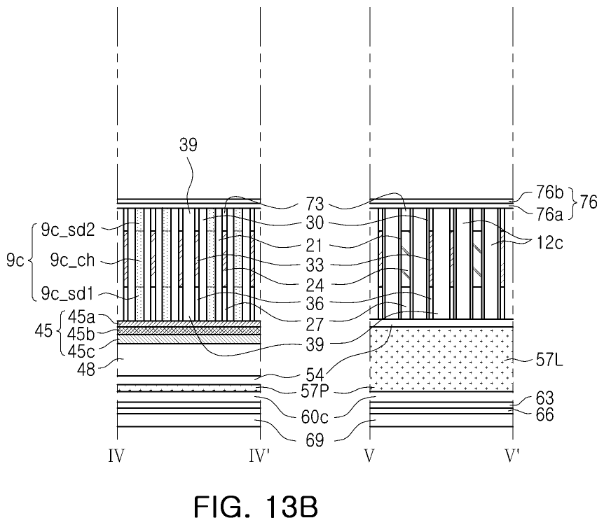

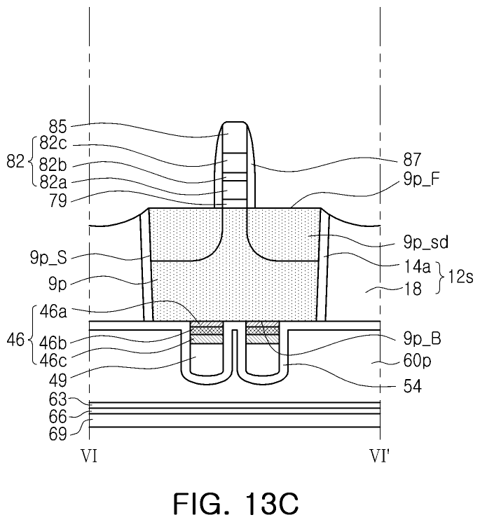

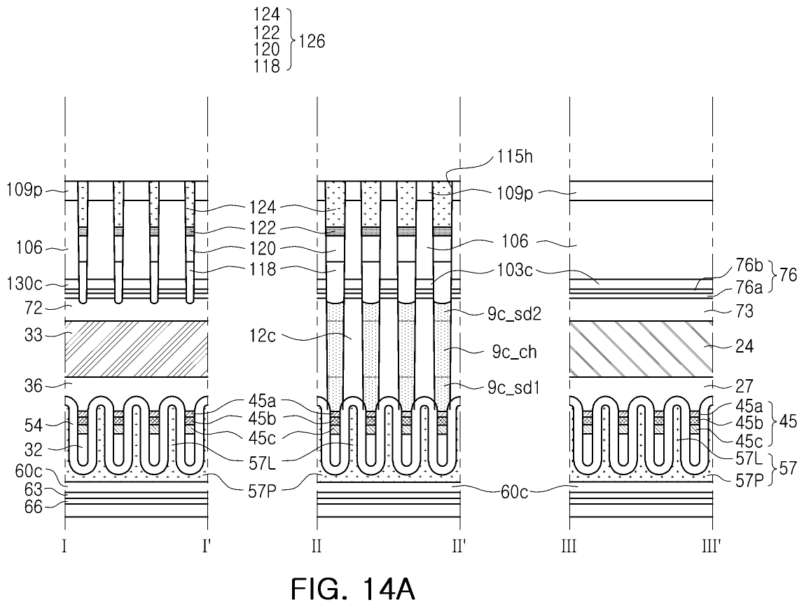

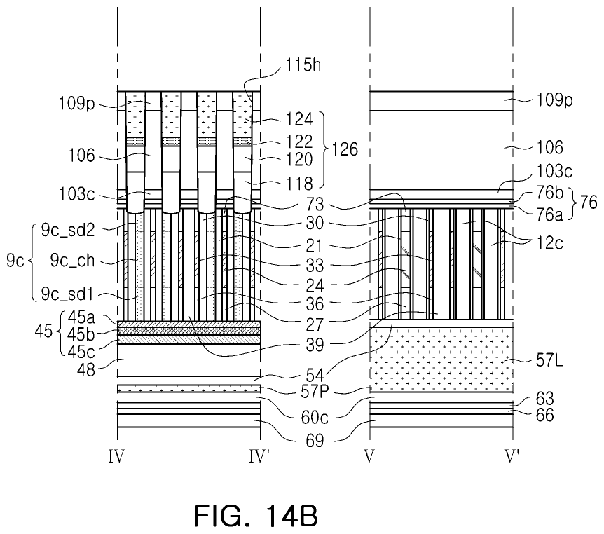

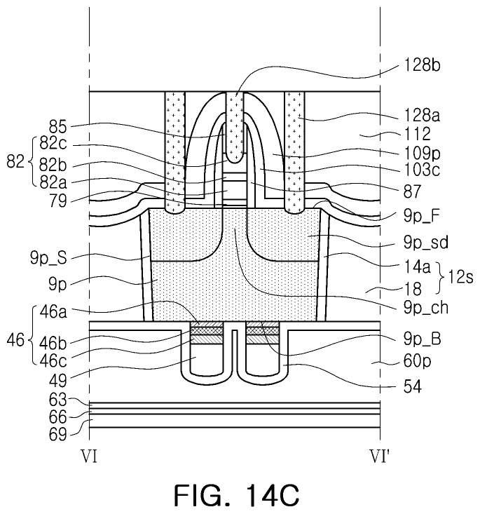

Example embodiments of a method of forming a semiconductor device will be described with reference to FIG. 4 and FIG. 5, FIG. 6A, FIG. 6B, FIG. 6C, FIG. 7, FIG. 8, FIG. 9, FIG. 10, FIG. 11A, FIG. 11B, FIG. 11C, FIG. 12A, FIG. 12B, FIG. 12C, FIG. 13A, FIG. 13B, FIG. 13C, FIG. 14A, FIG. 14B, and FIG. 14C. FIG. 4 is a process flow diagram illustrating a method of forming a semiconductor device according to an example embodiment of the present disclosure. FIGS. 5 to 14C are cross-sectional views illustrating example embodiments of a method of forming a semiconductor device. FIG. 5, FIG. 7, FIG. 8, FIG. 9, and FIG. 10 are top views for illustrating example embodiments of a method of forming a semiconductor device. FIG. 6A, FIG. 11A, FIG. 12A, FIG. 13A, and FIG. 14A are cross-sectional views illustrating a region taken along lines I-I′, II-II′, and III-III′ of FIG. 1. FIG. 6B, FIG. 11B, FIG. 12B, FIG. 13B, and FIG. 14B are cross-sectional views illustrating a region taken along lines IV-IV′ and V-V′ of FIG. 1. FIG. 6C, FIG. 11C, FIG. 12C, FIG. 13C, and FIG. 14C are cross-sectional views of a region taken along line VI-VI′ of FIG. 1.

Referring to FIG. 4, FIG. 5, FIG. 6A, FIG. 6B, and FIG. 6C, first preliminary cell semiconductor bodies 9a within the cell array region MCA and a peripheral semiconductor body 9p within the peripheral circuit region PA may be formed (S5). The first preliminary cell semiconductor bodies 9a and the peripheral semiconductor body 9p may be formed using a silicon on insulator (SOI) substrate. For example, in an SOI substrate including a lower single crystal semiconductor layer, an insulating layer, and an upper single crystal semiconductor layer, the upper single crystal semiconductor layer may be patterned by performing an etching process using the mask 10 on the upper single crystal semiconductor layer as an etching mask, and the first preliminary cell semiconductor bodies 9a and the peripheral semiconductor body 9p may be formed.

The mask 10 may include a plurality of layers. For example, the mask 10 may include a first mask layer 10a, a second mask layer 10b, and a third mask layer 10c, sequentially stacked.

The first preliminary cell semiconductor bodies 9a and the peripheral semiconductor body 9p may be formed on an insulating layer 6 of a SOI substrate. The insulating layer 6 may be formed on a lower substrate 3, which may be a lower single crystal semiconductor layer of the SOI substrate. The first preliminary cell semiconductor bodies 9a and the peripheral semiconductor body 9p may be formed of a single-crystal semiconductor, for example, single-crystal silicon.

Each of the first preliminary cell semiconductor bodies 9a may have a linear shape extending in a first direction Y.

Each of the first preliminary cell semiconductor bodies 9a and the peripheral semiconductor body 9p may have a positively inclined side surface. For example, the peripheral semiconductor body 9p may have a first surface 9p_F, in contact with the insulating layer 6 and a second surface 9p_B, in contact with the mask 10. A width of the first surface 9p_F may be greater than that of the second surface 9p_B.

Referring to FIG. 4, FIG. 7, FIG. 8, FIG. 9, FIG. 10, FIG. 11A, FIG. 11B, and FIG. 11C, device isolation regions may be formed (S10). The device isolation regions may include a cell device isolation region 12c on side surfaces of the first preliminary cell semiconductor bodies 9a and a peripheral device isolation region 12s on a side surface of the peripheral semiconductor bodies 9p.

The mask 10 may be removed while forming the device isolation regions or after forming the device isolation regions.

In an example, the peripheral device isolation region 12s may include an insulating liner 14 and a gap-fill insulating layer 18 on the insulating liner 14. The insulating liner 14 may include silicon oxide, and the gap-fill insulating layer 18 may include at least one of silicon oxide or a low-κ dielectric. The low-κ dielectric may be a dielectric having a dielectric constant lower than that of silicon oxide.

In an example, the cell device isolation region 12c may be formed of the same material as that of the insulating liner 14.

The first preliminary cell semiconductor bodies (9a in FIG. 5) may be patterned to form second preliminary cell semiconductor bodies (9b of FIG. 7) (S15). Each of the second preliminary cell semiconductor bodies (9b of FIG. 7) may have a bar shape extending in the first direction Y. A back gate trench may be formed while patterning the first preliminary cell semiconductor bodies (9a in FIG. 5).

Preliminary cell gates may be formed (S20). The preliminary cell gates may include a back gate dielectric layer 21 and a preliminary back gate electrode 23. Forming the preliminary back gates may include forming the back gate dielectric layer 21 covering an inner wall of the back gate trench formed while patterning the first preliminary cell semiconductor bodies (9a in FIG. 5), and forming the preliminary back gate electrode 23 partially filling the back gate trench on the back gate dielectric layer 21. Forming the preliminary back gates may further include forming an insulating layer 27 filling the remaining portion of the back gate trench on the preliminary back gate electrode 23.

The back gate dielectric layer 21 may be formed using at least one of a thermal oxidation process or a deposition process. When the back gate dielectric layer 21 is formed by sequentially performing a thermal oxidation process and a deposition process, a portion of the back gate dielectric layer 21 formed on surfaces of the second preliminary cell semiconductor bodies (9b in FIG. 7) exposed by the back gate trench may be thicker than the remaining portion by a thermal oxidation process.

The back gate trench may be filled with the back gate dielectric layer 21, the preliminary back gate electrode 23, and the insulating layer 27 in FIG. 11B, and the back gate trench may be defined as side surfaces of the back gate dielectric layer 21, the preliminary back gate electrode 23, and the insulating layer 27 and a bottom surface of the preliminary back gate electrode 23.

Cell semiconductor bodies (9c in FIG. 8) may be formed by patterning the second preliminary semiconductor bodies (9b in FIG. 7) (S25). A cell gate trench may be formed while patterning the second preliminary semiconductor bodies (9b of FIG. 7).

Preliminary cell gates may be formed (S30). The preliminary cell gates may include a cell gate dielectric layer 30 having a U-shape and a preliminary cell gate electrode 32 having a U-shape. Forming the preliminary cell gates may include forming the cell gate dielectric layer 30 covering an inner surface of the cell gate trench formed while pattering the second preliminary semiconductor bodies (9b in FIG. 7), and forming the preliminary cell gate electrode 32 on the cell gate dielectric layer 30. Forming the preliminary cell gates may include forming an insulating layer 39 filling the remaining portion of the cell gate trench on the preliminary cell gate electrode 32, and partially etching the preliminary cell gate electrode 32 and forming an insulating layer 36 formed by partially etching the preliminary cell gate electrode 32.

In the preliminary cell gate electrode 32, a line-shaped portion indicated by reference numeral 32 in FIG. 9 may be vertical portions extending in a vertical direction, perpendicular to an upper surface of the lower substrate 3, in FIG. 11A and FIG. 11B.

The cell gate dielectric layer 30 may be formed using at least one of a thermal oxidation process or a deposition process. When the cell gate dielectric layer 30 is formed by sequentially performing a thermal oxidation process and a deposition process, a portion of the cell gate dielectric layer 30 formed on surfaces of the cell semiconductor bodies 9c exposed by the cell gate trench may be thicker than the remaining portion by a thermal oxidation process.

The cell gate trench may be defined by outer and bottom surfaces of the cell gate dielectric layer 30 in FIG. 11B.

First cell source/drain regions 9c_sd1 may be formed in the cell semiconductor bodies 9c.

Bit lines 45 may be formed within the cell array region MCA (S35). The bit lines 45 may be formed by forming a first conductive layer 45a, a second conductive layer 45b, and a third conductive layer 45c, sequentially stacked, forming bit line capping layers 48 on the third conductive layer 45c, and patterning the first conductive layer 45a, the second conductive layer 45b, and the third conductive layer 45c by an etching process using the bit line capping layers 48 as an etching mask. Accordingly, each of the bit lines 45 may include the first conductive layer 45a, the second conductive layer 45b, and the third conductive layer 45c, sequentially stacked.

In an example, a peripheral conductive pattern 46 in contact with the second surface 9p_B of the peripheral semiconductor body 9p within the peripheral circuit region PA and a capping pattern 49 on the peripheral conductive pattern 46 may be formed.

The peripheral conductive pattern 46 and the capping pattern 49 may be formed simultaneously with the bit lines 45 and the bit line capping layers 48. Accordingly, the peripheral conductive pattern 46 includes a first conductive layer 46a, a second conductive layer 46b, and a third conductive layer 46c, sequentially stacked, in the same manner as the bit lines 45.

A lower insulating layer 54 conformally covering the bit lines 45 and the bit line capping layer 48 within the bit lines 45, and conformally covering the peripheral device isolation region 12s, the peripheral semiconductor body 9p, the peripheral conductive pattern 46, and the peripheral capping pattern 49 within the peripheral circuit region PA may be formed.

A shield structure 57 may be formed on the lower insulating layer 54 (S40). Forming the shield structure 57 may include forming a conductive layer on the lower insulating layer 54 within the cell array region MCA and the peripheral circuit region PA, and removing the conductive layer located within the cell array region MCA. Accordingly, the shield structure 57 may be formed within the cell array region MCA.

The shield structure 57 may include line portions 57L and a plate portion 57P. The line portions 57L may be positioned between structures including the bit lines 45 and the bit line capping patterns 48. The line portions 57L may be disposed between adjacent bit lines. The line portions 57L may extend from the plate portion 57P and include a portion positioned at a level higher than that of the bit line capping patterns 48. The plate portion 57P may have a plate shape connecting the line portions 57L to each other.

An peripheral lower insulating layer 60p may be formed on the lower insulating layer 54 within the peripheral circuit region PA.

An insulating layer 63 may be formed on the shield structure 57 and the peripheral lower insulating layer 60p.

A support substrate 69 and an insulating layer 66 on the support substrate 69 may be formed. The support substrate 69 may be a silicon substrate.

A wafer bonding process may be performed to bond the insulating layer 63 and the insulating layer 66.

Referring to FIG. 12A, FIG. 12B, and FIG. 12C, the support substrate 69 in FIG. 11A, FIG. 11B, and FIG. 11C may be positioned therebelow, and the lower substrate 3 may be positioned thereabove. Subsequently, the lower substrate 3 may be removed so that the insulating layer 6 is exposed.

Referring to FIG. 4, FIG. 13A, FIG. 13B, and FIG. 13C, a planarization process may be performed. The planarization process may be performed using at least one of a chemical mechanical polishing process or an etch-back process. The planarization process may be performed until the peripheral semiconductor bodies 9p and the cell semiconductor bodies 9c are exposed. By the planarization process, the insulating layer 6 may be removed, a portion of the insulating liner 14 may be removed, and portions of the preliminary back gate electrode 23 and the preliminary cell gate electrode 32 may be removed.

The preliminary back gate electrode 23 and the preliminary cell gate electrode 32 may be partially etched to form a back gate electrode 24 and a cell gate electrode 33. Upper ends of the back gate electrode 24 and the cell gate electrode 33 may be disposed at a lower level than upper surfaces of the cell semiconductor bodies 9c.

An insulating layer 73 within a space formed by partially etching the preliminary back gate electrode 23 and an insulating layer 72 within a space formed by partially etching the preliminary cell gate electrode 32 may be formed.

Second cell source/drain regions 9c_sd2 may be formed in upper regions of the cell semiconductor bodies 9c. Within each of the cell semiconductor bodies 9c, a cell channel region 9c_ch may be formed between the first cell source/drain region 9c_sd1 and the second cell source/drain region 9c_sd2.

The first cell source/drain region 9c_sd1, the second cell source/drain region 9c_sd2, the cell channel region 9c_ch, the cell gate electrode 33, and the cell gate dielectric layer 30 may form a cell transistor. The cell gate electrode 33 may be a word line.

Within the cell array region MCA, a buffer insulating layer 76 may be formed to protect the cell array region MCA. The buffer insulating layer 76 may include at least one layer, for example, a first buffer insulating layer 76a and a second buffer insulating layer 76b, sequentially stacked.

A peripheral transistor including a peripheral gate 78 and a peripheral source/drain region 9p_sd may be formed (S45). The peripheral gate 78 may include a peripheral gate dielectric layer 79 and a peripheral gate electrode 82 on the peripheral gate dielectric layer 79.

Forming the peripheral gate 78 may include forming the peripheral gate dielectric layer 79 and conductive layers 82a, 82b, and 82c on the peripheral semiconductor body 9p, forming a peripheral gate capping pattern 85 on the conductive layers 82a, 82b, and 82c, and forming the peripheral gate electrode 82 by etching the conductive layers 82a, 82b, and 82c by an etching process using the peripheral gate capping pattern 85 as an etching mask.

The conductive layers 82a, 82b, and 82c may include a first conductive layer 82a, a second conductive layer 82b, and a third conductive layer 82c, sequentially stacked.

A peripheral gate spacer 87 may be formed on side surfaces of the peripheral gate electrode 82 and the peripheral gate capping pattern 85.

Peripheral source/drain regions 9p_sd may be formed in the peripheral semiconductor body 9p. Peripheral source/drain regions 9p_sd may be formed on sides of the peripheral gate electrode 82. For example, the peripheral source/drain regions 9p_sd may be formed in the peripheral semiconductor body 9p on opposite sides of the peripheral gate electrode 82.

Referring to FIG. 4, FIG. 14A, FIG. 14B and FIG. 14C, a lower insulating liner layer 103c covering the cell array region MCA and the peripheral circuit region PA may be formed. The lower insulating liner layer 103c may be an insulating liner.

Within the cell array region MCA, a cell interlayer insulating layer 106 may be formed on the lower insulating liner layer 103c. Forming the cell interlayer insulating layer 106 may include forming an insulating layer on the lower insulating liner layer 103c, and removing an insulating layer in the peripheral circuit region PA to form an insulating layer remaining in the cell array region MCA.

An upper insulating liner layer 109p covering the cell interlayer insulating layer 106 in the cell array region MCA and the lower insulating liner layer 103c in the peripheral circuit region PA may be formed. Within the peripheral circuit region PA, a peripheral interlayer insulating layer 112 may be formed on the upper insulating liner layer 109p.

Contact structures, including the cell contact structures 126, the peripheral source/drain contact plug 128a, and peripheral gate contact plug 128b may be formed (S50).

Each of the cell contact structures 126 may be formed in a hole 115h. The holes 115h may penetrate through the buffer insulating layer 76, the lower insulating liner layer 103c, the cell interlayer insulating layer 106, and the upper insulating liner layer 109p. The cell contact structures 126 in the holes 115h may be electrically connected to the second cell source/drain region 9c_sd2.

Each of the cell contact structures 126 may include a first layer 118, a second layer 120, a third layer 122, and a fourth layer 124.

In one example, the first layer 118 may be formed of epitaxial silicon, for example, epitaxial silicon having N-type conductivity. When the first layer 118 is formed of epitaxial silicon, the second layer 120 may be formed of polysilicon, for example, polysilicon having N-type conductivity.

In another example, the first layer 118 may be formed of polysilicon, for example, polysilicon having N-type conductivity. When the first layer 118 is formed of polysilicon, the first layer 118 and the second layer 120 may be formed of a single layer.

The peripheral source/drain contact plug 128a may be electrically connected to the peripheral source/drain region 9p_sd through the lower insulating liner layer 103c, the upper insulating liner layer 109p, and the peripheral interlayer insulating layer 112, within the peripheral circuit region PA. The peripheral gate contact plug 128b may be electrically connected to the peripheral gate electrode 82 through the lower insulating liner layer 103c, the upper insulating liner layer 109p, and the peripheral gate capping pattern 85, within the peripheral circuit region PA.

Referring to FIG. 1, FIG. 2A, FIG. 2B, and FIG. 2C, a data storage structure 141 may be formed on the cell contact structures 126 within the cell array region MCA. The data storage structure 141 may include first electrodes 135 electrically connected to the cell contact structures 126, a dielectric layer 137 on the first electrodes 135, and a second electrode 139 on the dielectric layer 137.

An upper insulating layer 143 covering the peripheral interlayer insulating layer 112 may be formed within the peripheral circuit region PA.

As set forth above, according to example embodiments, a cell vertical channel transistor including a vertical channel region in a cell array region may be provided, and a peripheral transistor may be provided including peripheral source/drain regions formed in a peripheral semiconductor body having a width of an upper region that is greater than a width of a lower region in a peripheral circuit region. A semiconductor device including the cell vertical channel transistor and peripheral transistors may have an increased degree of integration, and improved performance.

According to example embodiments, a back gate capable of suppressing or preventing a floating body effect occurring in the vertical channel region of the cell vertical channel transistor may be provided.

According to example embodiments, a shield pattern may serve to screen capacitive coupling between bit lines.

The various beneficial advantages and effects of the present disclosure are not limited to the above description, and will be more easily understood in the process of describing example embodiments of the present disclosure.

While example embodiments have been illustrated and described above, it will be apparent to those skilled in the art that modified examples and variations could be made without departing from the scope of the present disclosure as defined by the appended claims.

What is claimed is:

1. A semiconductor device comprising:
a lower structure including a bit line;
a cell semiconductor body disposed on the lower structure and vertically overlapping the bit line;
a peripheral semiconductor body disposed on the lower structure, the peripheral semiconductor body including a portion disposed at a same level as at least a portion of the cell semiconductor body;
a word line facing a first side surface of the cell semiconductor body; and
a cell gate dielectric layer disposed between the word line and the first side surface of the cell semiconductor body,
wherein the peripheral semiconductor body includes a lower region having a first width and an upper region having a second width,
wherein the upper region is disposed on the lower region, and
wherein the second width is greater than the first width.

2. The semiconductor device of claim 1, further comprising:
a peripheral isolation region disposed on a side surface of the peripheral semiconductor body; and
a peripheral insulating structure in contact with an upper surface of the peripheral isolation region,
wherein the peripheral isolation region includes:
a gap-fill insulating layer; and
a buffer liner disposed between the side surface of the peripheral semiconductor body and a side surface of the gap-fill insulating layer.

3. The semiconductor device of claim 2, wherein an upper end portion of the buffer liner and an upper surface of the gap-fill insulating layer are in contact with the peripheral insulating structure, and
a lower end portion of the buffer liner and a lower surface of the gap-fill insulating layer are in contact with the lower structure.

4. The semiconductor device of claim 2, wherein the buffer liner further includes a portion extending between an upper surface of the gap-fill insulating layer and the peripheral insulating structure.

5. The semiconductor device of claim 4, wherein the peripheral isolation region further includes an insulating liner between the buffer liner and the gap-fill insulating layer.

6. The semiconductor device of claim 5, wherein a material of the insulating liner is different from a material of the buffer liner and a material of the gap-fill insulating layer.

7. The semiconductor device of claim 2, wherein the peripheral isolation region further includes an insulating liner,
wherein the insulating liner is disposed between the side surface of the gap-fill insulating layer and the buffer liner, and disposed between an upper surface of the gap-fill insulating layer and the peripheral insulating structure.

8. The semiconductor device of claim 7, wherein an upper end portion of the buffer liner and each of an upper end portion of the insulating liner is disposed at a level lower than a level of an upper surface of the peripheral semiconductor body.

9. The semiconductor device of claim 7, wherein an upper end portion of the buffer liner is disposed at a level lower than a level of an upper end portion of the insulating liner.

10. The semiconductor device of claim 1, wherein each of the peripheral semiconductor body and the cell semiconductor body includes single crystal silicon.

11. The semiconductor device of claim 1, further comprising:
a peripheral gate disposed at a different level from the word line.

12. The semiconductor device of claim 1, further comprising:
a back gate electrode facing a second side surface of the cell semiconductor body,
wherein the back gate electrode is parallel to the word line, and
wherein at least a portion of the cell semiconductor body is disposed between the word line and the back gate electrode.

13. A semiconductor device, comprising:
a lower structure;
a vertical channel transistor disposed on the lower structure;
a peripheral semiconductor body disposed on the lower structure; and
a peripheral isolation region disposed on the lower structure and on a side surface of the peripheral semiconductor body,
wherein the vertical channel transistor includes:
a lower cell source/drain region disposed in a lower region of a cell semiconductor body;
an upper cell source/drain region disposed in an upper region of the cell semiconductor body;
a cell channel region in the cell semiconductor body disposed between the lower cell source/drain region and the upper cell source/drain region;
a cell gate electrode facing a first side surface of the cell channel region; and
a cell gate dielectric layer disposed between the first side surface of the cell channel region and the cell gate electrode,
wherein the lower structure includes a lower insulating layer and a bit line electrically connected to the lower cell source/drain region,
wherein the peripheral isolation region includes a gap-fill insulating layer and a buffer liner disposed between a side surface of the peripheral semiconductor body and a side surface of the gap-fill insulating layer, and
wherein a lower surface of the gap-fill insulating layer and a lower end portion of the buffer liner are in contact with the lower insulating layer of the lower structure.

14. The semiconductor device of claim 13, wherein a width of an upper surface of the peripheral semiconductor body is greater than a width of a lower surface of the peripheral semiconductor body.

15. The semiconductor device of claim 13, further comprising:
a peripheral insulating structure in contact with an upper surface of the peripheral isolation region,
wherein an upper end portion of the buffer liner of the peripheral isolation region is in contact with the peripheral insulating structure.

16. The semiconductor device of claim 15, wherein the peripheral isolation region further includes an insulating liner disposed between the side surface of the gap-fill insulating layer and the buffer liner, and disposed between an upper surface of the gap-fill insulating layer and the peripheral insulating structure.

17. The semiconductor device of claim 13, further comprising:
a contact structure disposed on the upper cell source/drain region and electrically connected to the upper cell source/drain region; and
a data storage structure disposed on the contact structure and electrically connected to the contact structure.

18. A semiconductor device, comprising:
a lower structure;
a vertical channel transistor disposed on the lower structure;
a peripheral semiconductor body disposed on the lower structure, at least a portion of a side surface of the peripheral semiconductor body having a negative slope; and
a peripheral isolation region disposed on the lower structure and on the side surface of the peripheral semiconductor body,
wherein the vertical channel transistor includes:
a lower cell source/drain region disposed in a lower region of a cell semiconductor body;
an upper cell source/drain region disposed in an upper region of the cell semiconductor body;
a cell channel region in the cell semiconductor body disposed between the lower cell source/drain region and the upper cell source/drain region;
a cell gate electrode facing a first side surface of the cell channel region; and
a cell gate dielectric layer disposed between the first side surface of the cell channel region and the cell gate electrode,
wherein the lower structure includes a bit line electrically connected to the lower cell source/drain region of the vertical channel transistor,
wherein the peripheral isolation region includes:
a gap-fill insulating layer; and
an insulating liner disposed between the side surface of the peripheral semiconductor body and a side surface of the gap-fill insulating layer,
wherein an upper end portion of the peripheral semiconductor body is disposed at a first height level,
wherein a lower end portion of the peripheral semiconductor body is disposed at a second height level,
wherein an upper end portion of the insulating liner is disposed at a third height level,
wherein a lower end portion of the insulating liner is disposed at a fourth height level, and
wherein a first difference between the first height level and the third height level is different from a second difference between the second height level and the fourth height level.

19. The semiconductor device of claim 18, wherein the first difference between the first height level and the third height level is greater than the second difference between the second height level and the fourth height level.

20. The semiconductor device of claim 19, further comprising:
a peripheral insulating structure in contact with an upper surface of the peripheral isolation region;
a contact structure disposed on the upper cell source/drain region and electrically connected to the upper cell source/drain region; and
a data storage structure disposed on the contact structure and electrically connected to the contact structure.
